(19) United States
(12) Patent Application Publication
(10) Pub. No.: US 2025/0275088 A1
(43) Pub. Date: Aug. 28, 2025

(54) DEVICE COMPRISING AN ELECTRONIC COMPONENT

(71) Applicant: Miba eMobility GmbH, Laakirchen (AT)

(72) Inventors: Alois SONNLEITNER, Straßwalchen (AT); Franz PÖHN, Pettenbach (AT)

(21) Appl. No.: 18/707,323

(22) PCT Filed: Nov. 3, 2022
(86) PCT No.: PCT/AT2022/060377

§ 371 Date: May 3, 2024

(30) Foreign Application Priority Data
Nov. 4, 2021 (AT) A 50869/2021

(51) Int. Cl. H05K 7/20; H05K 1/02

(52) U.S. Cl. CPC H05K 7/20254; H05K 1/0203; H05K 7/2039; H05K 7/20927

(57) ABSTRACT

A device comprising at least one electronic component or at least one electronic assembly, and at least one cooling and/or temperature-control element for the cooling and/or temperature control of the electronic component or of the electronic assembly, wherein the cooling and/or temperature-control element has at least one fluid channel for a cooling and/or temperature-control medium, and wherein the cooling and/or temperature-control element has at least one single-or multi-layer film, which forms at least part of the fluid channel and is in contact with the electronic component or the electronic assembly.

### RELATED APPLICATIONS

This application is a national stage under 35 U.S.C. § 371 of International Application No. PCT/AT2022/060377, filed Nov. 3, 2022, which claims priority of Austrian Patent Application No. A 50869/2021, filed Nov. 4, 2021.

### TECHNICAL FIELD

The field of the present disclosure relates to a device comprising at least one electronic component or at least one electronic assembly, and at least one cooling and/or temperature-control element for the cooling and/or temperature control of the electronic component or the electronic assembly, wherein the cooling and/or temperature-control element has at least one fluid channel for a cooling and/or temperature-control medium.

The field of the present disclosure further relates to a method for producing a device comprising at least one electronic component or at least one electronic assembly, and at least one cooling and/or temperature-control element for the cooling and/or temperature control of the electronic component or the electronic assembly, wherein, in the cooling and/or temperature-control element, at least one fluid channel for a cooling and/or temperature-control medium is formed.

### BACKGROUND

It is well known that electronic components, especially power electronics components, generate heat during operation. As a rule, this heat must be dissipated in order to enable undisturbed operation of the electronic components, in particular to prevent overheating.

A wide variety of coolers for cooling electronic components are already known from the prior art. By way of example, reference is made to the so-called heat pipes, in which the heat is removed via the evaporation of a liquid, wherein the vapor generated in the process is condensed again with a secondary cooler. The thermal energy released in the process is extracted from the system via the secondary circuit.

Liquid coolers for electronic components have also been described in the prior art. For example, DE 10 2007 015 859 A1 describes a device for the liquid cooling of electronic assemblies. In this regard, a primary heat exchanger is used, which consists of two half shells that are joined together in a pressure-tight manner with a non-detachable connection. Inside the two half shells, a semi-flex tube is attached in a serpentine shape.

The liquid cooling medium flows through the semi-flex tube, turning the half-shell system into a heat sink and/or cooling housing. The cooling housing assumes the function of the primary heat exchanger. The surface of the cooling housing serves as a thermal contact surface for the units to be cooled. Depending on the application, this surface can be equipped and/or contacted with waste heat producing electronic components.

DE 10 2014 216 170 B3 describes an electronic module with at least one power component and a cooler, which comprises a pin heat sink and heats the at least one power component via the pin heat sink and a cooling medium, wherein the at least one power component is connected to the pin heat sink via an electrically insulating connecting layer, wherein the pin heat sink comprises a base plate, which is floatingly mounted on the cooler via at least one first seal, wherein the at least one first seal is arranged in a first sealing groove formed in the cooler, and wherein at least one second seal is arranged in a second sealing groove formed in the cooler, wherein a cover covers the sealing groove, which is screwed to the cooler and is pressed onto the at least one second seal with a predeterminable force. The cooling medium is guided in a cavity which is formed between the pin heat sink, the cooler and the cover, wherein the base plate closes off the cavity at the top and cooling pins protrude from the base plate into the cavity, wherein the cover closes off the cavity at the bottom, and wherein the cooler closes off the cavity at the side.

As a rule, liquid cooling systems for electronic components have a relatively complex structure, as it is important to prevent the liquid from coming into contact with the electronic components.

### SUMMARY

A need remains for a device that creates a simple cooling system for an electronic component and/or an electronic assembly.

This need may be satisfied by the initially mentioned device, in which the cooling and/or temperature-control element has at least one single-layer or multi-layer film which forms at least part of the fluid channel, wherein the film is in contact with the electronic component or the electronic assembly.

Furthermore, the need may be satisfied by the initially mentioned method, in which it is provided that the cooling and/or temperature-control element is produced with at least one single-layer or multi-layer film, and at least part of the fluid channel is formed with said film, and the film is arranged in contact with the electronic component or the electronic assembly.

The advantage here is that the film can be used to compensate for different structural heights of electronic components within an electronic assembly relatively easily, as the film can at least approximately follow the height profile due to its flexibility. But even with just one electronic component, a simplification can be achieved through the improved contactability of the cooling and/or temperature-control element on its surface. In addition, a reduction in weight can also be achieved by the use of a film.

According to a preferred embodiment variant, it can be provided that the film is in direct contact with the electronic component or the electronic assembly. This means that no compensating masses, etc., are required, which can improve the heat transfer from the electronic component and/or the electronic assembly into the cooling medium.

To further improve the above effects, according to a further embodiment variant, it may be provided that the film is connected to a layer of a metal or a further single-layer or multi-layer film thus forming the fluid channel. The metal layer can also provide the device with greater resistance towards the outside against mechanical impacts. By using a further film, the cooling and/or temperature-control element can be arranged more easily and/or better within an electronic assembly, since the second surface can also be configured flexibly and can thus be brought into contact with further electronic components.

According to a further embodiment variant, it can be provided that the film has regions with different heat flux densities and/or is produced with sections/regions of different heat flux density (and/or different thermal conductivities and/or different thermal resistances and/or different heat transfer coefficients). It is thus possible to adapt the cooling and/or temperature-control element to the heat-emitting components so that, in the electronic assembly, at least some of the electronic components can have at least approximately the same surface temperature. It is thus also possible to improve and/or accelerate heat extraction in a hot-spot region, so that this region can be equipped with the same cooling and/or temperature-control element as for neighboring non-hot-spot regions.

According to an embodiment variant in this regard, it can be provided that the film is thinner in a region with a higher heat flux density than in a region with a lower heat flux density in comparison, wherein, according to a further embodiment variant, the thinner region is formed and/or produced by a material removal and/or the thicker region is formed and/or produced by a material application to the film. It is therefore relatively easy to provide the desired heat flux density (and/or different thermal conductivities and/or different thermal resistances and/or different heat transfer coefficients).

However, it can also be provided that the film is thicker in a region with a higher heat flux density than in a region with a lower heat flux density in comparison. For example, a thick metal layer can be provided.

According to another embodiment variant, it can be provided that at least one sensor element is arranged on the cooling and/or temperature-control element, which can also make it structurally simpler to monitor the cooling and/or temperature-control of the electronic component or the electronic assembly.

### BRIEF DESCRIPTION OF THE DRAWINGS

For the purpose of better understanding of the invention, it will be elucidated in more detail by means of the figures below.

These show in a simplified schematic representation:

FIG. 1 a section through a part of a first embodiment variant of a device;

FIG. 2 a section through an embodiment variant of the cooling and/or temperature-control element;

FIG. 3 a section through a further embodiment variant of the cooling and/or temperature-control element;

FIG. 4 a section through an embodiment variant of a cooling element for the cooling and/or temperature-control element;

FIG. 5 a top view of a part of a further embodiment variant of the device;

FIG. 6 a sectional view of a part of another embodiment variant of a device;

FIG. 7 a sectional view of a part of a further embodiment variant of a device;

FIG. 8 a sectional view of a part of a further embodiment variant of a device.

### DETAILED DESCRIPTION OF EXEMPLARY EMBODIMENTS

First of all, it is to be noted that in the different embodiments described, equal parts are provided with equal reference numbers and/or equal component designations, where the disclosures contained in the entire description may be analogously transferred to equal parts with equal reference numbers and/or equal component designations. Moreover, the specifications of location, such as at the top, at the bottom, at the side, chosen in the description refer to the directly described and depicted figure and in case of a change of position, these specifications of location are to be analogously transferred to the new position.

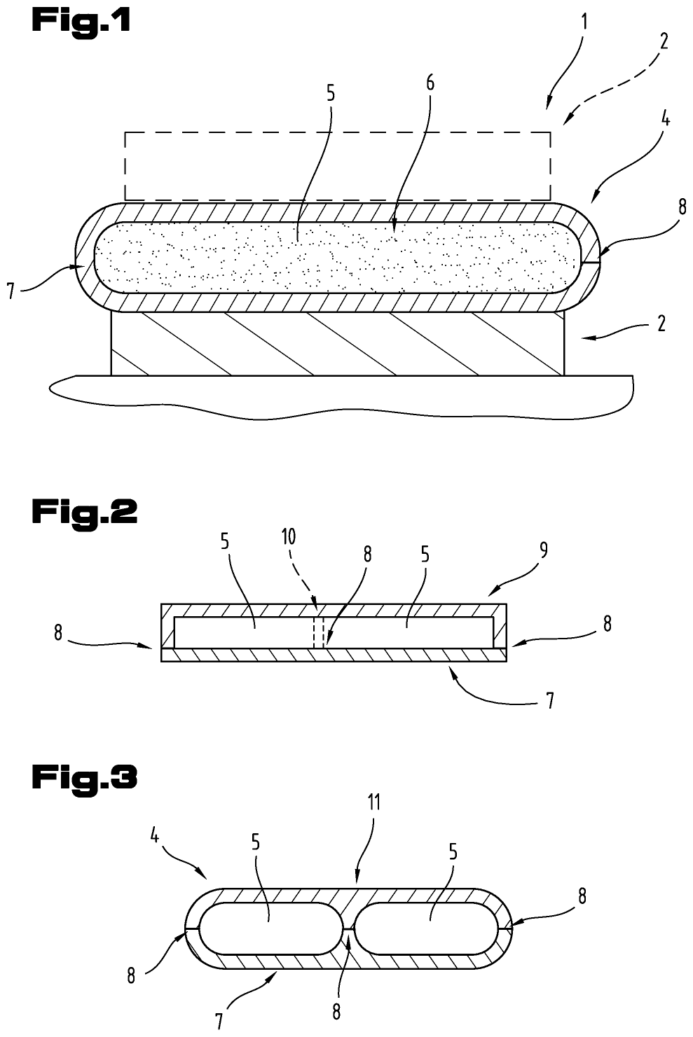

FIG. 1 shows a first embodiment variant of a device 1. The device 1 comprises at least one electronic component 2 or at least one electronic assembly 3 (see FIG. 6), which has such electronic components 2, and at least one cooling element 4 and/or temperature-control element for the cooling and/or temperature control of the electronic component 2 or the electronic assembly 3, and/or consists of these components.

The electronic component 2 can be, for example, a resistor, a diode, a transistor, a thyristor, an IGBT, a diac, a bipolar power transistor, a power MOSFET, a GTO thyristor, a triac, a diode, a power capacitor, an inductor (coil), etc.

The electronic assembly 3 can be, for example, a rectifier, an inverter, a transformer, a DC converter, an AC converter, a switched-mode power supply, etc.

In particular, the electronic component 2 and/or the electronic assembly 3 is a power electronics component and/or a power electronics assembly, in particular a high-performance electronics component and/or a high-performance electronics assembly. Power electronics comprises the conversion of electrical energy with switching electronic components. The heat output can be so high that the heat can no longer be dissipated to the environment by radiation or convection via air.

Such electronic components 2 and/or electronic assemblies 3 are used, for example, in a wind turbine, an electric motor, in a high voltage network, in medical technology (e.g. X-ray, MRI, CT devices), in vehicles (also with an internal combustion engine, e.g. for a control unit), etc.

For the sake of simplicity, the cooling element 4 and/or temperature-control element is referred to as cooling element 4 in the following. However, the function as a temperature-control element is not excluded by this, but should be read as well.

The cooling element 4 can extend over multiple or all electronic components 2 of an electronic assembly 3, so that these can be cooled with just one cooling element 4. In principle, however, it is also possible to provide multiple cooling elements 4 per electronic component 2 and/or per electronic assembly 3, for example two or three or four, so that these are divided between two or three or four, etc. cooling elements 4. Furthermore, a cooling element 4 can cover the entire surface of one side of the electronic component 2 or the electronic assembly 3 (as shown in FIGS. 1 and 6), or only part of it.

It is also possible for the/one cooling element 4 to be arranged between two electronic components 2 (as shown in FIG. 1) or electronic assemblies 3.

The cooling element 4 has at least one fluid channel 5. The fluid channel 5 can be configured to have a straight extension. However, it is also possible that the fluid channel 5 is arranged or formed in a meandering manner, as can be seen in FIG. 5, which shows a top view of a part of a cooling element 4.

In general, the fluid channel 5 extends from a coolant inlet, not shown in further detail, to a coolant outlet, not shown in further detail, of the cooling element 4.

The specific illustration of the course of the at least one fluid channel 5 in FIG. 5 is only to be understood as an example. The respective optimized course of the at least one fluid channel 5 depends, among other things, on the amount of heat to be dissipated, the geometry of the electronic component 2 and/or the electronic assembly 3, for example due to different heights of the electronic components 2 of an electronic assembly 3. It can also be provided for that more than one fluid channel 5 is formed and/or arranged in cooling element 4. In this case, it is advantageous if a common inlet is arranged in front of the multiple fluid channels 5 and a common outlet behind them, which can each be formed as collecting channels, from which the fluid channels 5 branch out or into which they flow. However, it is also possible that each fluid channel 5 has its own coolant inlet and/or its own coolant outlet.

The coolant inlet and the coolant outlet can be arranged and/or formed on one side or on different sides of the cooling element 4.

A cooling medium 6 (and/or temperature-control medium) flows through the fluid channel 5. The cooling medium 6 can be liquid or gaseous, preferably a liquid is used, for example a water-glycol mixture or a cooling oil.

It is provided that the cooling element 4 has at least one single-layer or multi-layer film 7, which forms at least part of the fluid channel 5 and which is in contact with the electronic component 2 or the electronic assembly 3. Preferably, the film 7 is in direct contact with the electronic component 2 or the electronic assembly 3, as this means that the heat transfer is not disturbed by intermediate elements. However, at least one intermediate element can be arranged between the film 7 and the electronic component 2 or the electronic assembly 3, for example a leveling compound to compensate for different heights of the contact surface(s), although this is not necessary due to the flexibility of the film 7. It is advantageous if the intermediate element has good thermal conductivity so that the heat transfer from the electronic component 2 or from the electronic assembly 3 to the cooling element 4 is not reduced (too much).

The fluid channel 5 can be formed with a film 7, as shown in FIG. 1. For this purpose, film sections are arranged on top of each other and these are connected to each other (in a fluid-tight manner) in at least one connecting area 8, as shown in FIG. 1.

According to another embodiment variant shown in FIG. 2, it is also possible for the film 7 to be connected to a layer 9 made of a metal, for example aluminum. This layer 9 can have a higher stiffness than the film 7, in particular also be inherently stiff, so that the cooling element 4 can have a hard shell that protects it better from external influences. The connecting areas 8 can, for example, be formed on webs or side walls of the layer 9 extending in the direction of the film 7. If a non-straight extension of the fluid channel 5 or more than one fluid channel 5 is to be formed, at least one rib 10 extending in the direction of the film 7 can be provided, which defines a further connecting area 8.

The connection between the layer 9 and the film 7 can, for example, be configured as an adhesive bond.

In general, the connecting areas 8 can be configured as materially bonded and, if necessary, positive locking connections.

FIG. 3 shows another embodiment variant of the cooling element 4 in cross-section.

The cooling element 4 comprises the film 7 and a further single-layer or multi-layer film 11. The film 7 and the further film 11 are connected to one another in connecting areas 8, forming at least one fluid channel 5 (in the embodiment variant shown, the cooling element 4 has two fluid channels 5) between the film 7 and the further film 11. As in the embodiment variant of the cooling element 4 according to FIG. 2, there are at least two connecting areas 8 (in the embodiment variant of the cooling element 4 shown, there are three).

Generally, in the embodiments variants of the cooling element 4, the connecting areas 8 extend along the longitudinal extension of the at least one fluid channel 5, wherein unconnected regions remain between the connecting areas 8, in which the at least one fluid channel 5 is/is being formed by the spacing of the film 4 from itself (FIG. 1) or from the layer 9 (FIG. 2) or from the further film 11 (FIG. 3).

The film 7 and the optionally present further film 11, which is in particular arranged above the film 7, extend across a surface which preferably at least approximately, in particular to 100%, corresponds to the area of the cooling element 4 (as in a plan view).

In the cooling device 2 according to the embodiment variant of FIG. 2, the film 4 can also extend across at least approximately, in particular to 100%, the surface of the cooling element 4 (as viewed in a plan view).

In all embodiment variants of the cooling element 4, preferably no measures other than the connection of the film 4 to itself or to the layer 9 or to the further film 11 are required to form the at least one fluid channel 5. The at least one fluid channel 5 is therefore not formed by separate components, but is formed by the only partial connection of the film 7 to itself or to the layer 9 or to the further film 11. The wall or walls of the at least one fluid channel 5 is/are therefore formed by the film 7 and possibly the layer 9 or the further film 11, preferably half of each. However, it may also be provided that the wall or walls of the at least one fluid channel 5 is/are formed by the further layer 9 (as shown in FIG. 2) or the further film 11.

As already mentioned, the film 7 is flexible (in particular non-rigid); the further film 11 can also be flexible (in particular non-rigid). Alternatively or additionally, the film 4 and/or the further film 11 can be shaped, in wherein, in this case, the flexibility of the film 4 and/or the film 11 can be reduced at least in the region of the at least one fluid channel 5. It can thus be achieved that the film 4 retains its shape at least in the region of the at least one fluid channel 5.

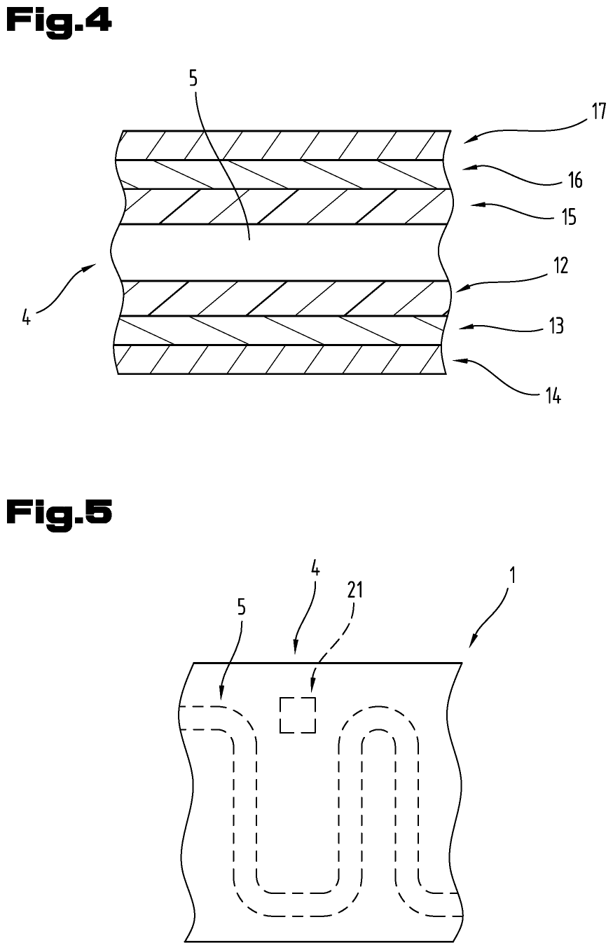

As shown in FIG. 4, the film 4 preferably consists of a laminate having a first plastic layer 12, a reinforcing layer 13 connected thereto, a metal layer 14 connected to the reinforcing layer 13 or a metallized further plastic film connected to the reinforcing layer 13. The film 4 may also comprise only the plastic layer 12 or the plastic layer 12 and the reinforcing layer 13 or the plastic layer 12 and the metal layer 14 or the metallized further plastic film.

In the preferred embodiment variant, the film 7 lies with a plastic layer or the metal layer 14, which may be electrically insulated, against the electronic component 2 and/or the electronic assembly 3.

The film 7 can also be formed only from multiple plastic layers that are the same or different from one another.

The further film 11 can have the same structure as the film 7 or a different structure.

Preferably, the further film 10 comprises and/or consists of at least a second plastic layer 15. The second plastic layer 15 is partially connected to the first plastic layer 12 of the laminate of the film 7 in the connecting areas 8, so that at least one cavity is formed between the connecting areas 8, which cavity forms the at least one fluid channel 5.

It may also be provided that the further film 11 consists of a laminate comprising the second plastic layer 15, a reinforcing layer 16 connected thereto, a metal layer 17 connected to the reinforcing layer 16 or a metallized further plastic layer connected to the reinforcing layer 16.

In general, other laminates can be used as well. For example, merely the film 7 can be provided with the metal layer 14 or merely the further film 11 can be provided with the metal layer 17. Likewise, merely the film 7 can comprise the reinforcing layer 13 or merely the further film 11 can comprise the reinforcing layer 16. Likewise, structures of the film 7 and/or the further film 11 with more than three layers are possible. However, preferably, the film 7 and the further film 11 are designed equally.

The reinforcing layer 16 and/or the metal layer 17 of the further film 11 can differ from the reinforcing layer 13 and/or the metal layer 14 of the film 7. However, preferably, the two reinforcing layers 13, 16 and/or the two metal layer 14, 17 are configured equally.

The two films 7, 11 are arranged such that the two plastic layers 12, 15 lie against one another and the mentioned partial connected is formed via these plastic layer 12, 16. If the further film 11 comprises (merely) the second plastic layer 15, said second plastic layer 15 is arranged directly adjacent to the plastic layer 12 of the film 7 and connected thereto.

Instead of a metal layer 14, 17, a metalized further plastic layer can also be used, wherein, in this case, the metalization is preferably arranged between the reinforcing layer 13, 16 and the further plastic layer.

The first plastic layer 13 and/or the second plastic layer 16 and/or the metalized further plastic layer preferably consists/consist to at least 80 wt. %, in particular at least 90 wt. %, of a thermoplastic material or of an elastomer. The thermoplastic material can be selected from a group comprising and/or consisting of polyethylene (PE), polyoxymethylene (POM), polyamide (PA), in particular PA 6, PA 66, PA 11, PA 12, PA 610, PA 612, polyphenylene sulphide (PPS), polyethylene terephthalate (PET), crosslinked polyolefins, preferably polypropylene (PP), barrier plastics, such as polyethylene vinyl alcohol (EVOH) or polyvinylidene chloride (PVDC). The elastomer can be selected from a group comprising and/or consisting of thermoplastic elastomers such as thermoplastic vulcanizates, olefin-, amine-, ester-based thermoplastic polyurethanes, in particular ether-based/ester-based thermoplastic elastomers, styrene block copolymers, silicone elastomers.

At this point, it should be noted that the term plastic material is understood as a synthetic or natural polymer produced from corresponding monomers.

Preferably, the first plastic layer 12 and/or the second plastic layer 15 and/or the metalized further plastic layer consists/consist of a so-called sealing film. This has the advantage that the films 7, 11 can be connected to one another directly.

However, it is also possible to use other plastic materials, such as thermosetting plastic materials and/or thermosetting materials, which are then for example adhered to one another by means of an adhesive. Two-part adhesive systems based on polyurethane or silicone or hot melt adhesive systems are particularly suitable for this purpose.

Preferably, the reinforcing layer/reinforcing layers 13, 16 comprise/comprises a or consist/consists of a fiber reinforcement.

The fiber reinforcement is preferably formed as a separate layer, which is arranged between the plastic layer 12 and/or the plastic layer 15 and the metal layer 14 and/or the metal layer 17 or the metalized further plastic layer. If cavities are formed in the fiber reinforcement, these can also be at least partially filled with the plastic material of the plastic layer 12 and/or the plastic layer 15 or the metalized further plastic film.

The fiber reinforcement can be formed of fibers and/or threads, which are selected from a group comprising or consisting of glass fibers, aramid fibers, carbon fibers, mineral fibers such as basalt fibers, natural fibers such as hemp, sisal and combinations thereof.

Preferably, glass fibers are used as fiber reinforcement. The proportion of the fibers, in particular the glass fibers, in the fiber reinforcement can amount to at least 80 wt. %, in particular at least 90 wt. %. Preferably, the fibers and/or threads of the fiber reinforcement consist merely of glass fibers.

The fibers and/or threads can be present in the fiber reinforcement as roving, for example as a non-woven fabric. However, preferably the fibers and/or threads become a woven fabric or a knitted fabric. In this regard, it is also possible that the woven or knitted fabric is merely present in some regions and that the remaining regions of the fiber reinforcement are formed by a roving.

It is also possible that rubberized fibers and/or threads are used as or for the fiber reinforcement.

When using a woven fabric, different types of weaves are possible, in particular plain, twill or satin weave. Preferably, a plain weave is used.

However, it is also possible to use an open-mesh glass fabric or glass roving.

The fiber reinforcement can be formed as a single layer. However, it is also possible that the fiber reinforcement comprises several, optionally separate, individual layers, for example two or three, wherein at least individual or several individual layers can at least in some regions, preferably entirely, consist of fibers and/or threads different as compared to the rest of the individual layers.

In the alternative or in addition to the fiber reinforcement, the reinforcing layer(s) 13, 16 can comprise a mineral filling. For example, calcium carbonate, talc, quartz, wollastonite, kaolin or mica can be used as a mineral filling (mineral filler material).

The metal layer 15, 17 in particular is an aluminum layer. However, other materials such as copper or silver can also be used.

The metal layer 15, 17 can have a layer thickness of between 5 μm and 100 μm.

In case of the use of the metalized further plastic layer, the mentioned metals can be used for the metalization. Preferably, the metalization has a layer thickness selected from a range of between 5 nm and 100 nm. The metal vapor deposition of the further plastic layer can be carried out by means of a method known from the prior art.

The plastic layer 12 and/or the plastic layer 15 and/or the further plastic layer, which comprise the metalization, can have a layer thickness of between 10 μm and 200 μm.

The layer thickness of the reinforcing layer(s) 14, 16 may amount to between 5 μm and 50 μm.

The film 7 and/or the further film 11 can in particular comprise the following structure in the indicated order:
plastic layer 12 and/or plastic layer 15 of PP;
reinforcing layer 13, 16 of a glass fiber fabric;
metal layer 14, 17 of aluminum with a layer thickness of 12 μm.

In case of the further film 11 consisting merely of the plastic layer 15, preferably a polyethylene terephthalate (PET) is used as the plastic material for it.

The film 7 and/or the further film 11 can also comprise at least one further layer, such as at least one further reinforcing layer and/or at least one primer layer and/or at least one thermotropic layer.

Although the film 7 and the further film 11, if it also is a film laminate, can in general be used in the form of individual films for producing the cooling element 4, such that the film laminate(s) are only formed in the course of the production of the cooling element 4, it is advantageous if the first film 7 and/or the further film 11 are used as a (laminated) semi-finished product.

For connecting the individual layers of the laminate or the laminates, these can be adhered to one another by means of adhesives. The aforementioned adhesives are suitable for this purpose. Besides adhesives, coextrusion and extrusion coating can also be used as joining options. Of course, a combination is also possible in which multiple plastic materials are coextruded and adhesively laminated to one another with an extrusion-coated metal or (fiber) reinforcing layer. In general, all known methods can be used for producing composite films and/or film laminates.

It is also possible for fluid channels 5 to be arranged in multiple layers one above the other, for which purpose the cooling element 4 can, for example, have a third single-layer or multi-layer film. It can be configured as described above and partially connected to the film 7 or the further film 11.

The described partial connection of the film 7 to the further film 11 and/or an additional film and/or the two plastic layers 12, 15 of the laminates can be established in a laminating press. In this regard, the connection can be established by the effect of an increased temperature and an increased pressure, as is known from laminating and/or heat sealing. The specific temperature depends on the used plastic materials.

Instead of the laminating device, a press can also be used, especially for the production of long fiber reinforced films 7, 11. At this, the fibers are impregnated and pressed with the plastic material, which results in the fiber reinforced film material.

The connection of the films 7, 11 to each other can be achieved in a materially bonded manner either by welding or by gluing, wherein mixed variants of these processes are also possible. In general, other methods can be used for this purpose as well.

For example, temperature pulse welding, laser welding, IR welding, ultrasonic welding, high-frequency welding can be used as welding methods.

Further and possibly independent embodiment variants of the device 1 and/or of the cooling element 4 are shown in FIGS. 6 to 8, wherein again, equal reference numbers and/or component designations are used for equal parts as in FIGS. 1 through 5. In order to avoid unnecessary repetitions, it is pointed to/reference is made to the detailed description regarding FIGS. 1 to 5.

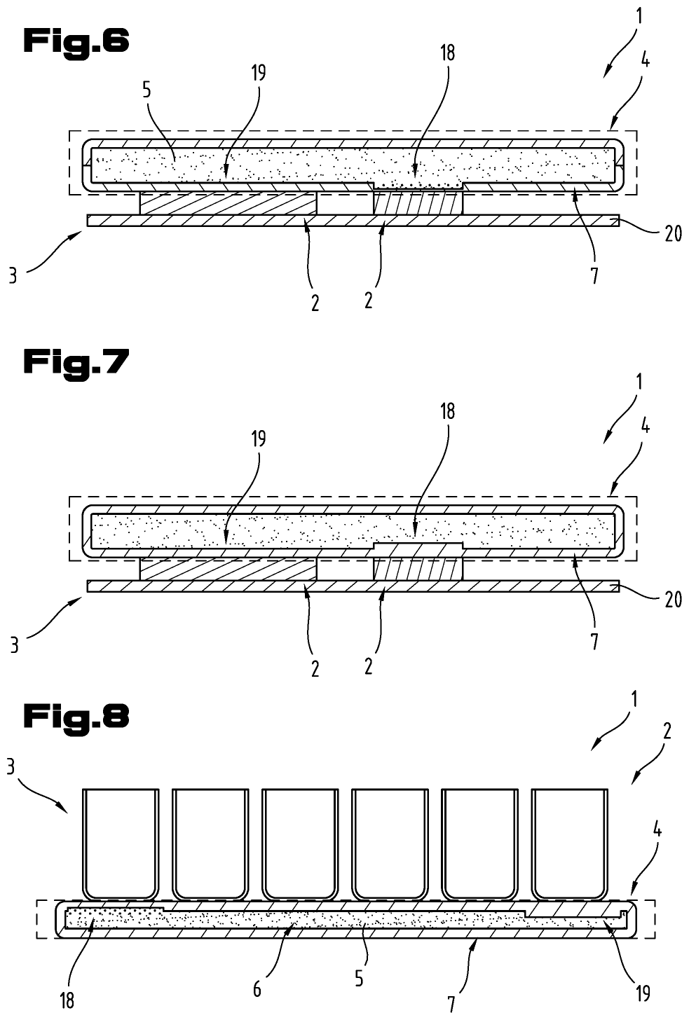

In the devices 1 shown in FIGS. 6 and 7, the cooling element 4 has regions with different heat flux densities.

The heat flux density is understood to mean the heat transferred per transfer surface and time interval, i.e. the thermal output per surface.

Furthermore, the regions of different heat flux densities are provided on the same side, i.e. the regions of different heat flux densities affect the same surface (the same contact surface, such as the underside, for example) of the cooling element 4. If the cooling element 4 is arranged between two electronic components 2 or electronic assemblies 3, the regions of different heat flux densities may also refer to the top side relative to the bottom side.

The regions with different heat flux densities can be provided in a wide variety of ways, for example by processing a material with higher thermal conductivity during the manufacture of the film 4 and/or the film 11 for a region with a higher heat flux density in the film 7 and/or the film 11. For example, thermally conductive particles, e.g. made of metal, can also be processed in this region.

FIGS. 6 and 7 show the preferred embodiment variants of the invention for producing the regions with different heat flux densities.

For example, it is possible for the region with a higher heat flux density to be thinner than the region with a lower heat flux density in comparison. In FIG. 6, a first region 18 and a second region 19 are shown in the film 7 for clarification. In the first region 18, the film 7 is thinner than in the second region 19, so that the film 7 has a higher heat flux density in the first region 18 than in the second region 19. The thinner first region 18 can be produced by material removal. The material removal can be carried out in this first region 18 from the inside and/or from the outside, for example by laser ablation, mechanical methods such as cutting or scraping, etc. Methods other than those mentioned can also be used.

However, it can also be provided that the film is thicker in a region with a higher heat flux density than in a region with a lower heat flux density in comparison. For example, a thick metal layer can be provided.

The material removal in the first region 18 can only affect one layer of the film 7 if it is multi-layered. However, the material can also be removed over multiple layers. In general, the material removal can be between 0% and 80%, in particular between 5% and 70%, for example between 10% and 50%, of the total layer thickness of the film 7. The exact value depends on the desired heat dissipation in this first region 18.

It should be mentioned at this point that, in general, more than two regions with different heat flux densities can also be formed. The illustrations in FIGS. 6 and 7 merely serve to clarify the principle.

According to another method, alternative or additional to material removal, the region with a higher heat flux density can be made thicker than the region with a lower heat flux density by applying material in order to set regions with different heat flux densities. In FIG. 7, the first region 18 has a material application, while the second region 19 does not. The material can again be applied from the outside or the inside.

The material can be applied, for example, by bonding, printing, vapor deposition, etc., although other methods can also be used. By the material application, the layer thickness of the film 7 can be increased in the region with the lower heat flux density by between 0% and 200%, in particular between 10% and 100%, for example between 20% and 50%, relative to the initial layer thickness of the film 7 before the material application. The exact value depends on the desired heat dissipation in this region with the lower heat flux density.

A combination of material application in one region and material removal in another region is also possible within the scope of the present disclosure. Furthermore, it is possible that in the case of more than two regions with different heat flux densities, the layer thicknesses of the regions differ from one another, i.e. that the material removal and/or material application does not take place to the same extent in all regions with reduced heat flux density.

For example, a plastic material can be used as the material for the material application, in particular the plastic material from which the layer of the film 7 on which the material is applied is formed. However, another material can also be used, such as carbon or aluminum.

The regions of different heat flux density can be used to ensure that the same surface temperature is achieved for all elements to be cooled, for example, with different heat flux density and/or different thermal conductivity of the elements to be cooled. In another application, for example, heat conduction and heat transfer can be improved by removing the film 7 in so-called hot-spot regions, thus achieving such a high heat flux density in such a region, for example, that the boiling point of the coolant is not exceeded in the hot-spot region.

For example, to illustrate the application of the different heat flux densities, FIGS. 6 and 7 each show an electronic assembly 3 with two electronic components 2 on a circuit board 20. In FIG. 6, the right-hand electronic component 2 has a higher heat generation than the left-hand electronic component 2. To take this into account, the film 7 is thinner in the first region 18 than in the second region 19 to increase the heat flux density. Since the left-hand electronic component 2 requires the normal cooling capacity that the cooling element 4 can provide, the first region 18 is made thicker by material application.

In FIG. 7, in contrast, the right-hand electronic component 2 generates less heat than the left-hand electronic component 2. However, since the left-hand electronic component 2 requires the normal cooling capacity that the cooling element 4 can provide, the first region 18 is made thicker by material application.

In the embodiment variant of this principle with material application and/or material removal according to FIG. 8, it is used to compensate for inhomogeneities in a flow field of the cooling medium 6 in such a way that poorer heat transfer in the edge region of the fluid channel 5 (first region 18) is compensated for by better heat dissipation in the film 7 through material removal (film 5). The material removal can increase the flow velocity of the cooling medium 6 in this region. Conversely, in a region with excessive heat dissipation (second region 19 in FIG. 8), the flow velocity of the cooling medium 6 can be reduced by material application. This embodiment variant is particularly advantageous if, as shown in FIG. 8, more than two electronic components 2 are cooled using a cooling element 4 with only one fluid channel 5.

FIG. 8 also shows that more than two electronic components 2 can be in direct contact with the cooling element 4 so that they are cooled with just one cooling element 4.

As can be seen from FIG. 5, according to another embodiment variant of the device 1, the cooling element 4 can have at least one sensor element 21. The sensor element 21 can be a temperature sensor, for example. Furthermore, it can be arranged on or in the film 7 or on or in the film 11.

The exemplary embodiments show possible embodiment variants, while it should be noted at this point that combinations of the individual embodiment variants are also possible.

Furthermore, the cooling element 4 with the different heat flux densities and/or different heat transfer coefficients can represent a separate invention independent of the device 1. In particular, this cooling element 4 is configured as described above. Preferably, the different heat flux densities and/or different heat transfer coefficients are formed by material removal and/or material application.

Finally, as a matter of form, it should be noted that for ease of understanding of the structure of the device 1 and/or of the cooling element 4, these are not obligatorily depicted to scale.

1. A device comprising at least one electronic component or at least one electronic assembly, and comprising at least one cooling and/or temperature-control element for the cooling and/or temperature control of the electronic component or of the electronic assembly, wherein the cooling and/or temperature-control element has at least one fluid channel for a cooling and/or temperature-control medium, and the cooling and/or temperature-control element has at least one single- or multi-layer film, which forms at least part of the fluid channel and is in contact with the electronic component or the electronic assembly.

2. The device according to claim 1, characterized in that the film is in direct contact with the electronic component or the electronic assembly.

3. The device according to claim 1, characterized in that the film is connected to a layer of a metal or a further single-layer or multi-layer film thus forming the fluid channel.

4. The device according to claim 1, characterized in that the film has regions with different heat flux densities or different heat transfer coefficients.

5. The device according to claim 4, characterized in that the film is thinner in a region with a higher heat flux density than in a region with a lower heat flux density in comparison.

6. The device according to claim 4, characterized in that the film is thicker in a region with a higher heat flux density than in a region with a lower heat flux density in comparison.

7. The device according to claim 5, characterized in that the thinner region is formed by a material removal and/or the region that is thicker in comparison is formed by a material application.

8. The device according to claim 1, characterized in that at least one sensor element is arranged on the cooling and/or temperature-control element.

9. A method for producing a device comprising at least one electronic component or at least one electronic assembly, and at least one cooling and/or temperature-control element for the cooling and/or temperature control of the electronic component or the electronic assembly, wherein at least one fluid channel for a cooling and/or temperature-control medium is formed in the cooling and/or temperature-control element, and the cooling and/or temperature-control element is produced with at least one single-layer or multi-layer film, and at least part of the fluid channel is formed with this film, and that the film is arranged to be in contact with the electronic component or the electronic assembly.

10. The method according to claim 9, characterized in that the film is produced with sections of different heat flux density or different heat transfer coefficients.

11. The method according to claim 10, characterized in that the regions of different heat flux density or different heat transfer coefficients are produced by material removal from and/or material application to the film.
